(19) United States
(12) Patent Application Publication
(10) Pub. No.: US 2024/0105717 A1
(43) Pub. Date: Mar. 28, 2024

(54) SEMICONDUCTOR DEVICE

(71) Applicant: SAMSUNG ELECTRONICS CO., LTD., Suwon-si, Gyeonggi-do (KR)

(72) Inventors: Sunme LIM, Suwon-si, Gyeonggi-do (KR); Changjoon YOON, Suwon-si (KR); Yeji LEE, Suwon-si (KR); Heejun CHO, Suwon-si (KR)

(21) Appl. No.: 18/234,987

(22) Filed: Aug. 17, 2023

(30) Foreign Application Priority Data
Sep. 28, 2022 (KR) 10-2022-0122994

(51) Int. Cl. H01L 27/088; H01L 21/8234; H01L 29/06; H01L 29/08; H01L 29/423; H01L 29/66; H01L 29/775

(52) U.S. Cl. CPC H01L 27/088; H01L 21/823412; H01L 21/823418; H01L 21/823481; H01L 29/0673; H01L 29/0847; H01L 29/42392; H01L 29/66439; H01L 29/66545; H01L 29/775

(57) ABSTRACT

A semiconductor device may include a first nanosheet structure having a first width, a second nanosheet structure having a second width and a diffusion break pattern disposed between the first and second nanosheet structures in a first direction. A first epitaxial pattern is disposed between the first nanosheet structure and the diffusion break pattern and is in direct contact therewith. A second epitaxial pattern is disposed between the second nanosheet structure and the diffusion break pattern and is in direct contact therewith. At least one of imaginary first lines connecting a first contact point of an end portion between the diffusion break pattern and the first epitaxial pattern and a second contact point at an end portion between the diffusion break pattern and the second epitaxial pattern extends to have an angle less than about 30 degrees with respect to the first direction.

### CROSS-REFERENCE TO RELATED APPLICATION

This application claims priority under 35 U.S.C. § 119 to Korean Patent Application No. 10-2022-0122994, filed on Sep. 28, 2022 in the Korean Intellectual Property Office, the disclosure of which is incorporated by reference in its entirety herein.

### 1. TECHNICAL FIELD

Embodiments of the present disclosure relate to a semiconductor device. Particularly, embodiments of the present disclosure relate to a semiconductor device including multi-bridge channel field effect transistors (MBC FET).

### 2. DISCUSSION OF RELATED ART

Research is being conducted concerning multi-bridge channel field effect transistors that include a plurality of vertically stacked channels. A standard cell including the multi-bridge channel field effect transistors may be formed in the semiconductor device.

### SUMMARY

Example embodiments provide a semiconductor device having increased electrical characteristics.

According to an embodiment of the present disclosure, a semiconductor device includes a first nanosheet structure on a substrate. The first nanosheet structure has a first width in a second direction parallel to an upper surface of the substrate. The first nanosheet structure includes silicon patterns that are spaced apart from each other in a vertical direction perpendicular to the upper surface of the substrate. A second nanosheet structure is spaced apart from the first nanosheet structure in a first direction perpendicular to the second direction on the substrate and parallel to the upper surface of the substrate. The second nanosheet structure has a second width in the second direction greater than the first width. The second nanosheet structure includes silicon patterns that are spaced apart from each other in the vertical direction. A diffusion break pattern is disposed between the first and second nanosheet structures in the first direction. A first epitaxial pattern is disposed between the first nanosheet structure and the diffusion break pattern in the first direction. The first epitaxial pattern directly contacts the first nanosheet structure and the diffusion break pattern, respectively. A second epitaxial pattern is disposed between the second nanosheet, structure and the diffusion break pattern in the first direction. The second epitaxial pattern directly contacts the second nanosheet structure and the diffusion break pattern, respectively. At least one of imaginary first lines connecting a first contact point of an end portion positioned in the second direction between the diffusion break pattern and the first epitaxial pattern and a second contact point at an end portion in the second direction between the diffusion break pattern and the second epitaxial pattern extends to have an angle less than about 30 degrees with respect to the first direction.

According to an embodiment of the present disclosure, a semiconductor device includes a plurality of first nanosheet structures on a substrate. The plurality of first nanosheet structures are spaced apart from each other in a first direction parallel to an upper surface of the substrate. Each of the plurality of first nanosheet structures has a first width in a second direction perpendicular to the first direction and parallel to the upper surface of the substrate. Each of the plurality of first nanosheet structures includes silicon patterns that are spaced apart from each other in a vertical direction perpendicular to the upper surface of the substrate. A second nanosheet structure is spaced apart from the plurality of first nanosheet structures in the first direction on the substrate. The second nanosheet structure has a second width in the second direction greater than the first width. The second nanosheet structure includes silicon patterns that are spaced apart from each other in the vertical direction. A diffusion break pattern is disposed between a first nanosheet structure of the plurality of first nanosheet structures and the second nanosheet structure that are adjacent to each other in the first direction. A first epitaxial pattern is between adjacent first nanosheet structures of the plurality of first nanosheet structures. A second epitaxial pattern is disposed between the first nanosheet structure and the diffusion break pattern. The second epitaxial pattern directly contacts the first nanosheet structure and the diffusion break pattern, respectively. A third epitaxial pattern is disposed between the second nanosheet structure and the diffusion break pattern. The third epitaxial pattern directly contacts the second nanosheet structure and the diffusion break pattern, respectively. First gate structures cover the plurality of first nanosheet structures. The first gate structures extend in the second direction. A second gate structure covers the second nanosheet structure. The second gate structure extends in the second direction. A volume of the first epitaxial pattern and a volume of the second epitaxial pattern are different from each other.

According to an embodiment of the present disclosure, a semiconductor device includes a first transistor on a substrate. The first transistor includes a first nanosheet structure having a first width in a second direction parallel to an upper surface of the substrate. A first gate structure covers the first nanosheet structure and extends in the second direction. First epitaxial patterns are on both sides of the first gate structure. The first epitaxial patterns are directly connected to the first nanosheet structure. A second transistor is on the substrate. The second transistor includes a second nanosheet structure having a second width in the second direction greater than the first width. A second gate structure covers the second nanosheet structure and extends in the second direction. Second epitaxial patterns are on both sides of the second gate structure. The second epitaxial patterns are directly connected to the second nanosheet structure. A diffusion break pattern is disposed between the first transistor and the second transistor. The first and second transistors are electrically isolated from each other by the diffusion break pattern. A first side of the diffusion break pattern directly contacts one of the first epitaxial patterns, and a second side of the diffusion break pattern directly contacts one of the second epitaxial patterns. At least one of imaginary lines connecting a first contact point of an end portion positioned in the second direction between the diffusion break pattern and a first epitaxial pattern of the first epitaxial patterns and a second contact point at an end portion positioned in the second direction between the diffusion break pattern and a second epitaxial pattern of the second epitaxial patterns extends to have an angle less than about 30 degrees with respect to a first direction perpendicular to the second direction and parallel to the upper surface of the substrate.

In embodiments of the present disclosure, the semiconductor device may have a reduction in defects of a multi-bridge channel transistor disposed adjacent to the diffusion break pattern.

### BRIEF DESCRIPTION OF THE DRAWINGS

Example embodiments of the present disclosure will be more clearly understood from the following detailed description taken in conjunction with the accompanying drawings. FIGS. 1 to 20 represent non-limiting, example embodiments as described herein.

FIGS. 1, 3, 5 and 7 are perspective views illustrating a method for manufacturing a semiconductor device according to embodiments of the present disclosure;

FIGS. 2, 4, 6, 8, 9, 11 and 13 are plan views illustrating a method for manufacturing a semiconductor device according to embodiments of the present disclosure;

FIGS. 10, 12 and 14 are cross-sectional views illustrating a method for manufacturing a semiconductor device according to embodiments of the present disclosure;

FIG. 15 is a plan view of a semiconductor device according to an embodiment of the present disclosure;

FIG. 16 is a plan view of a first fin structure formed in a manufacturing process of a semiconductor device according to an embodiment of the present disclosure;

FIG. 17 is a plan view of a semiconductor device according to an embodiment of the present disclosure;

FIG. 18 is a plan view of a first fin structure formed in a manufacturing process of a semiconductor device according to an embodiment of the present disclosure;

FIG. 19 is a plan view of a semiconductor device according to an embodiment of the present disclosure; and

FIG. 20 is a plan view of a first fin structure formed in a manufacturing process of a semiconductor device according to an embodiment of the present disclosure.

### DETAILED DESCRIPTION OF EMBODIMENTS

Hereinafter, embodiments of the present disclosure will be described in detail with reference to the accompanying drawings.

Hereinafter, two directions substantially parallel to an upper surface of a substrate and substantially perpendicular to each other may be defined as first and second directions, respectively, and a direction substantially perpendicular to the upper surface of the substrate may be defined as a vertical direction.

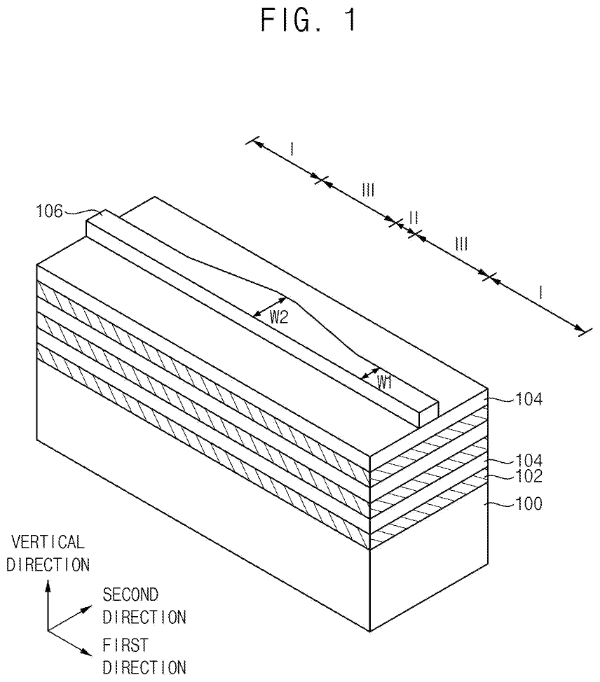

FIGS. 1 to 14 are plan views, cross-sectional views, and perspective views illustrating a method for manufacturing a semiconductor device according to embodiments of the present disclosure.

A method for forming a standard cell including multi-bridge field effect transistors may be described.

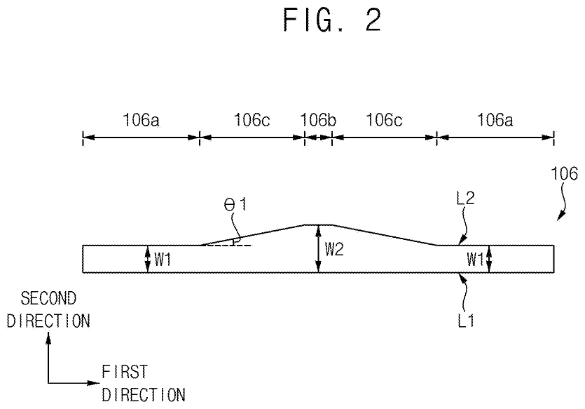

Referring to FIGS. 1 and 2, a silicon germanium layer 102 and a silicon layer 104 may be alternately and repeatedly stacked on a substrate 100 (e.g., in the vertical direction). In an embodiment, a mask layer may be formed on an uppermost silicon layer 104. The mask layer may be patterned to form a mask pattern 106 on the uppermost silicon layer 104.

In an embodiment, the substrate 100 may include a single crystal silicon substrate. The silicon germanium layer 102 and the silicon layer 104 may be formed by a selective epitaxial growth process. The silicon germanium layer 102 formed on the substrate 100 may be formed using an upper surface of the substrate 100 as a seed. However, embodiments of the present disclosure are not necessarily limited thereto.

For example, in an embodiment, the silicon layer 104 may be formed by performing a selective epitaxial growth process using a silicon source gas such as disilane (Si₂H₆) gas. The silicon layer 104 may include single crystal silicon.

In an embodiment, the silicon germanium layer 102 may be formed by, e.g., a selective epitaxial growth process using a silicon source gas such as dichlorosilane (SiH₂C₁₂) gas or a germanium source gas such as germanium tetrahydrogen (GeH₄) gas. The silicon germanium layer 102 may include single crystal silicon germanium. However, embodiments of the present disclosure are not necessarily limited thereto.

The mask layer may include, e.g., a nitride such as silicon nitride. The mask pattern 106 may extend in the first direction, and may have a line shape.

As shown in FIG. 2, in a plan view, the mask pattern 106 may have a first side L1 and a second side L2 opposite to the first side L1. The first side L1 of the mask pattern 106 may have a straight line extending in the first direction, and the second side L2 of the mask pattern 106 may have a straight line extending in the first direction and an oblique line with respect to the first direction.

The substrate 100 may include a first region I, a second region II and a third region III, and the third region III may be disposed between the first and second regions I and II (e.g., in the first direction). The first to third regions I, II, and III may include a surface of the substrate 100 and a region extending above the surface of the substrate 100. The first to third regions I, II, and III may be arranged in the first direction.

The first region I may be a region where a first gate structure of a first multi-bridge channel transistor is formed, and the second region II may be a region where a second gate structure of a second multi-bridge channel transistor is formed. A diffusion break pattern may be disposed in the third region III. The third region III may be disposed between opposite sidewalls of neighboring first and second gate structures.

In an embodiment, an impurity region serving as one of source/drain of the first multi-bridge channel transistor adjacent to the diffusion break pattern and an impurity region serving as one of source/drain of the second multi-bridge channel transistor adjacent to the diffusion break pattern may be disposed in the third region III.

The mask pattern 106 may extend in the first direction on the first to third regions I, II, and III. The mask pattern 106 may include a first portion 106a on the first region I, a second portion 106b on the second region II, and a third portion 106c on the third region III.

In an embodiment, the first portion 106a of the mask pattern may have a first width W1 in the second direction, and both sidewalk of the first portion 106a. in the second direction may have a straight line shape. The second portion 106b of the mask pattern fray have a second width W2 that is greater than the first width W1 in the second direction, and both sidewalls of the second portion 106b in the second direction may have a straight line shape.

The third portion 106c of the mask pattern may be positioned between the first and second portions 106a and 106b, and one sidewall of the third portion 106c positioned in the second direction may have a sloped shape (e.g., a tapered shape). Accordingly, a width in the second direction of the third portion 106c may gradually increase from the first portion 106a towards the second portion 106b. The second side L2 of the third. portion 106c may have an oblique line shape with respect to the first direction. In an embodiment, the second side L2 of the third portion 106c may obliquely extend to have an angle θ1 that is less than about 30 degrees with respect to the first direction. For example, in an embodiment the second side L2 of the third portion 106c may obliquely extend to have an angle less than about 15 degrees with respect to the first direction. In an embodiment, the first side L1 of the third portion 106c may extend in a straight line in the first direction.

A photoresist pattern serving as an etching mask may be formed on the mask layer to form the mask pattern 106. In an embodiment, a reticle pattern may be used in a photo process for forming the photoresist pattern, and the reticle pattern may have a shape substantially the same as a shape of the mask pattern 106 shown in FIG. 2. For example, in an embodiment the reticle pattern may include a first side having a straight line shape in the first direction, and a second side facing the first side including a straight line shape in the first direction and an oblique line shape with respect to the first direction. For example, in the reticle pattern corresponding to the third portion 106c of the mask pattern, a portion corresponding to the second side may obliquely extend to have an angle less than about 30 degrees with respect to the first direction. As such, the reticle pattern may not be bent to have an angle of 90 degrees at a portion where widths in the second direction are different from each other.

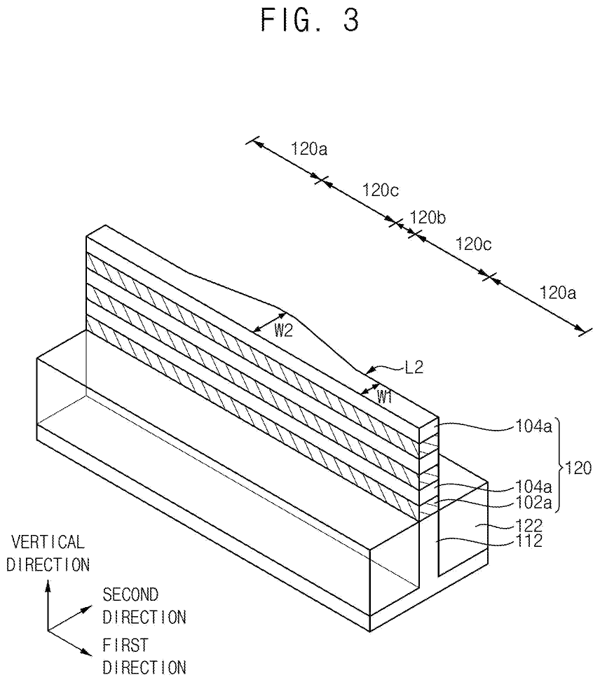

Referring to FIG. 3, the silicon germanium layers 102, the silicon layers 104, and an upper portion of the substrate 100 may be etched using the mask pattern 106 as an etching mask to form first trenches. In an embodiment, the etching process may include an anisotropic etching process. However, embodiments of the present disclosure are not necessarily limited thereto.

Accordingly, the upper portion of the substrate 100 may be etched to form a lower active pattern 112 extending in the first direction. A first fin structure 120 including a first silicon germanium pattern 102a and a first silicon pattern 104a alternately and repeatedly stacked (e.g., in the vertical direction) may be formed on the lower active pattern 112. The first fin structure 120 and the mask pattern 106 may be stacked on the lower active pattern 112 (e.g., in the vertical direction).

In an embodiment, the first fin structure 120 may be formed by the transferring of the mask pattern 106. Therefore, in a plan view, the first fin structure 120 may be substantially the same as the mask pattern 106. The first fin structure 120 may include first to third portions 120a, 120b, and 120c corresponding to the first to third portions 106a, 106b and 106c of the mask pattern 106.

In the plan view, the first portion 120a of the first fin structure may have the first width W1 in the second direction, and both sidewalls of the first portion 120a in the second direction may have a straight line shape (e.g., extending substantially in the first direction). The second portion 120b of the first fin structure may have the second width W2 greater than the first width W1 in the second direction, and both sidewalls of the second portion 120b in the second direction may have a straight line shape (e.g., extending substantially in the first direction). The third portion 120c of the first fin structure may be positioned between the first and second portions 120a and 120b (e.g., in the first direction), and one sidewall of the third portion 120c in the second direction may have a sloped shape (e.g., a tapered shape).

In an embodiment, a second side L2 of the third portion 120c of the first fin structure may obliquely extend to have an angle less than about 30 degrees with respect to the first direction. As such, the second side L2 of the third portion 120c of the first fin structure may have a gentle oblique shape.

An isolation layer may be formed to fill the first trenches. In an embodiment, an upper portion of the isolation layer may be removed to form an isolation pattern 122 covering sidewalls of the lower active pattern 112 in each of the first trenches. The mask pattern 106 may be removed. The first fin structure 120 may be formed between the isolation patterns 122 (e.g., in the second direction), and may protrude from the isolation patterns 122 (e.g., in the vertical direction).

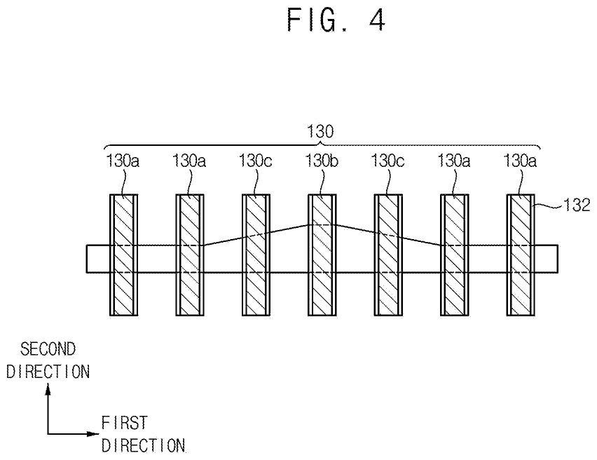

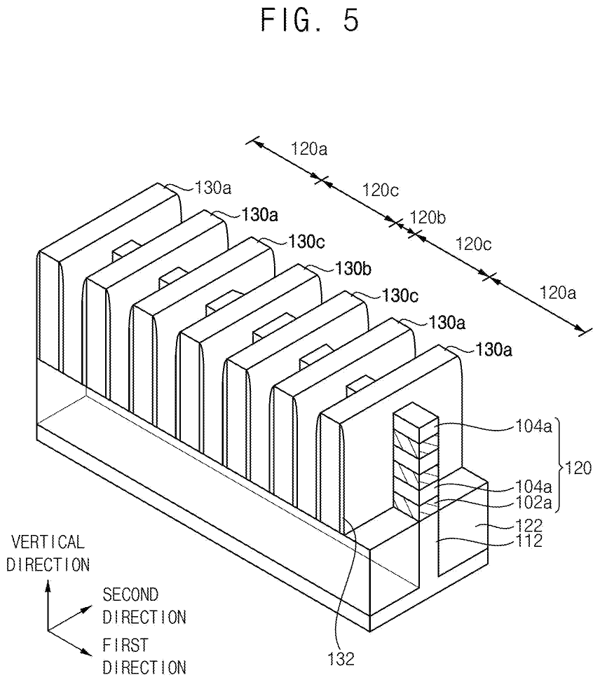

Referring to FIGS. 4 and 5, dummy gate structures 130 may be formed to partially cover the isolation pattern 122 and the first fin structure 120. The dummy gate structures 130 may extend longitudinally in the second direction. The dummy gate structures 130 may cross the first fin structure 120. In an embodiment, a first spacer 132 may be formed on sidewalls of each of the dummy gate structures 130.

The dummy gate structures 130 may be spaced apart from each other in the first direction. In an embodiment, the dummy gate structures 130 may have the same width to each other. However, embodiments of the present disclosure are not necessarily limited thereto.

The dummy gate structures 130 may be disposed at positions for forming the first gate structure, the second gate structure, and the diffusion break pattern, respectively. In an embodiment, the dummy gate structures 130 may include a first dummy gate structure 130a formed on the first portion 120a of the first fin structure, a second dummy gate structure 130b formed on the second portion 120b of the first fin structure, and a third dummy gate structure 130c formed on the third portion 120c of the first fin structure. The first dummy gate structure 130a may be replaced with a first gate structure by subsequent processes. The second dummy gate structure 130b may be replaced with a second gate structure by subsequent processes. The third dummy gate structure 130c may be replaced with a diffusion break pattern by subsequent processes.

If the angle of the second side of the third portion 120c of the first fin structure is greater than about 30 degrees with respect to the first direction, a sidewall profile of the third dummy gate structure 130c formed on the third portion 120c may not be in a straight line parallel to the second direction, and may include, e.g., a curved portion. Therefore, the first spacer 132 may not be uniformly formed on the sidewalls of the third dummy gate structure 130c. For example, the first spacer 132 may not be formed to have uniform thickness from the sidewalls of the third dummy gate structure 130c.

In an embodiment, in the plan view, the angle of the second side of the third portion 120c of the first fin structure may be gentle to have an angle less than about 30 degrees with respect to the first direction, and thus the sidewall profile of the third dummy gate structure 130c may have a straight line shape substantially parallel to the second direction. For example, the sidewall profile of the third dummy gate structure 130c may not have a curved portion. Accordingly, the first spacer 132 may be uniformly formed on the sidewalls of the third dummy gate structure 130c. For example, the first spacer 132 may be formed to have uniform thickness from the sidewalls of the third dummy gate structure 130c.

The second sides of the first and second portions 120a and 120b of the first fin structure have straight line shapes parallel to the first direction. Thus, each of the first and second dummy gate structures 130a and 130b may have a straight line shape substantially parallel to the second direction. Accordingly, the first spacers 132 may be uniformly formed on sidewalls of the first and second dummy gate structures 130a and 130b.

In an embodiment, the dummy gate structures 130 may be spaced apart in the first direction to have equal intervals.

In an embodiment, the dummy gate structure 130 may include a dummy gate insulation pattern, a dummy gate electrode, and a dummy gate mask pattern.

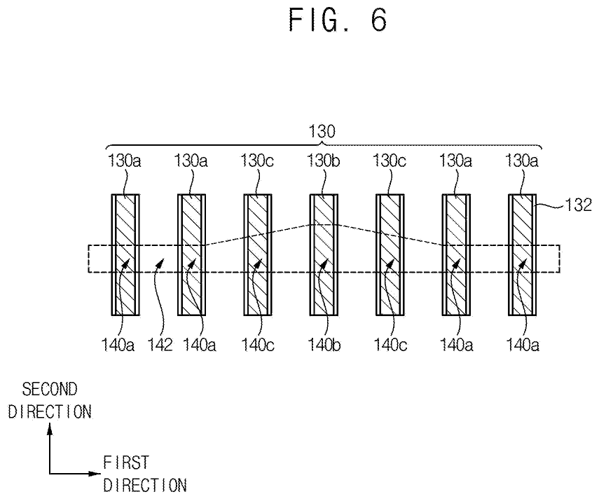

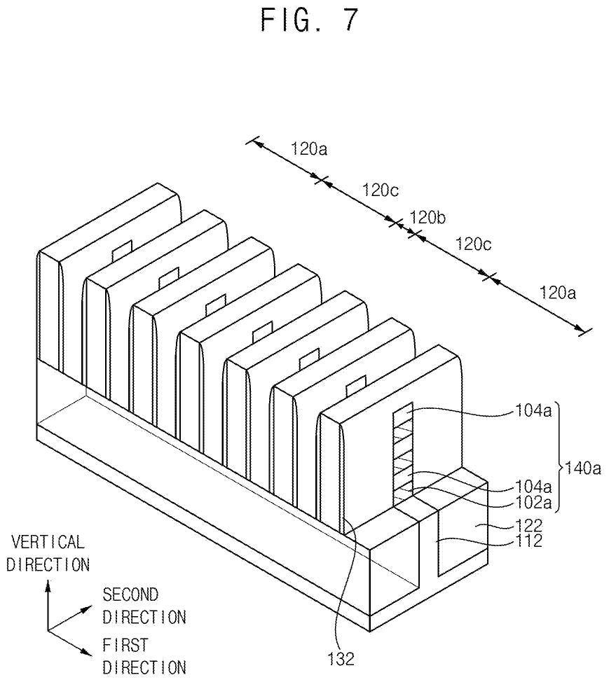

Referring to FIGS. 6 and 7, the first fin structure 120 between the dummy gate structures 130 may be removed to form first openings 142. For example, the first openings 142 may be formed between the first spacers 132 (e.g., in the first direction).

By the removing process of the first fin structure 120, the first fin structure 120 may be separated to form preliminary nanosheet structures 140a, 140b, and 140c under the dummy gate structures 130. For example, a first preliminary nanosheet structure 140a may be formed under the first dummy gate structure 130a. A second preliminary nanosheet structure 140b may be formed under the second dummy gate structure 130b. A third preliminary nanosheet structure 140c may be formed under the third dummy gate structure 130c.

The first to third preliminary nanosheet structures 140a, 140b, and 140c may be arranged in the first direction, and may be spaced apart from each other in the first direction. Each of the first to third preliminary nanosheet structures 140a, 140b, and 140c may include the first silicon germanium patterns 102a and the first silicon patterns 104a alternately and repeatedly stacked (e.g., in the vertical direction).

The first preliminary nanosheet structure 140a may have the first width W1 in the second direction, and the second preliminary nanosheet structure 140b may have the second width W2 in the second direction. In the plan view, one sidewall positioned in the second direction of the third preliminary nanosheet structure 140c may have a gentle slope of an angle less than about 30 degrees. For example, a second side of the third preliminary nanosheet structure 140c may have an angle less than about 30 degrees with respect to the first direction.

The lower active pattern 112 may be exposed by a bottom of the first opening 142 between the first to third preliminary nanosheet structures 140a, 140b, and 140c.

As the sidewall profile of the dummy gate structure 130 has the straight line shape in the second direction and the first spacers 132 are uniformly formed, the first fin structure 120 between the dummy gate structures 130 may be uniformly removed. Accordingly, the first openings 142 may have a uniform depth. Also, the first openings 142 may have increased accuracy in providing a target sidewall profile (e.g., a predetermined desired sidewall profile).

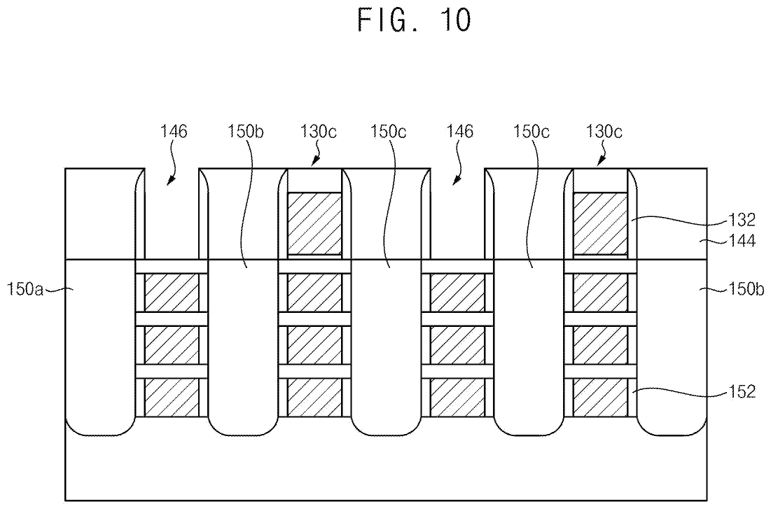

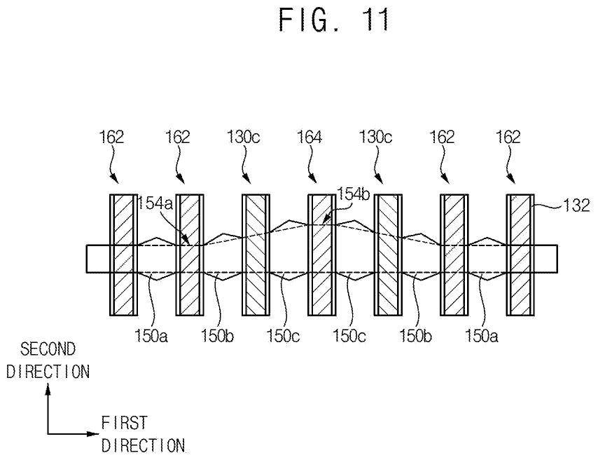

In an embodiment, after forming the first openings 142, an exposed sidewall of the first silicon germanium pattern 102a may be partially etched to form a recess. An inner spacer (FIG. 10, 152) including insulation material may be further formed in the recess.

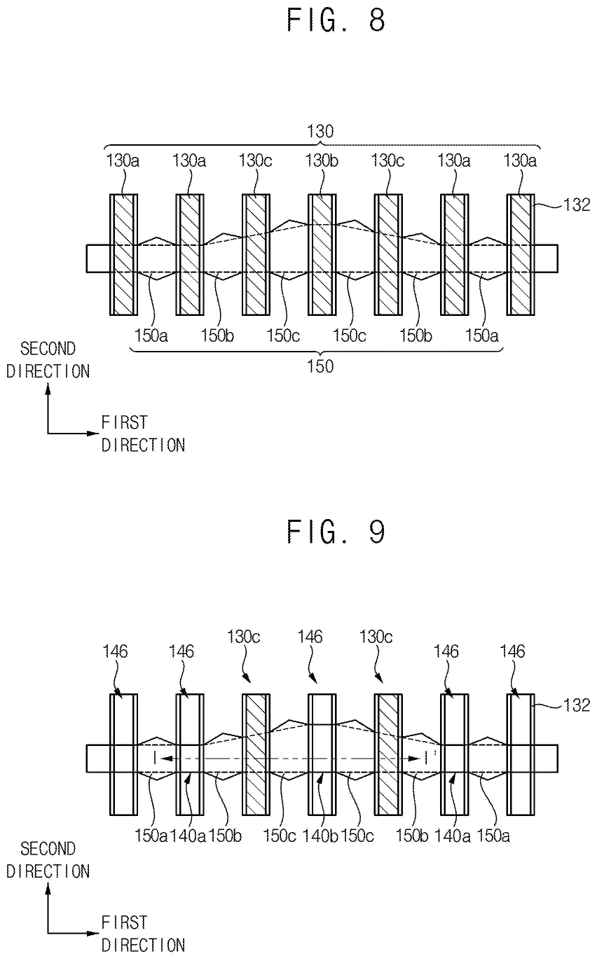

Referring to FIG. 8, a selective epitaxial growth process may be performed to form an epitaxial pattern 150 in each of the first openings 142. The epitaxial pattern 150 may include a semiconductor material.

In an embodiment, the first and second multi-bridge channel transistors may be N-type transistors. In this embodiment, each of the epitaxial patterns 150 may include single crystal silicon. In an embodiment, the first and second multi-bridge channel transistors may be P-type transistors. In this embodiment, each of the epitaxial patterns 150 may include single crystal silicon germanium. However, embodiments of the present disclosure are not necessarily limited thereto.

In an embodiment, impurities may be doped in situ during the performance of the selective epitaxial growth process. Accordingly, the epitaxial pattern 150 may serve as source/drain regions of the multi-bridge channel transistors subsequently formed.

In the selective epitaxial growth process, crystal growth may be performed in the vertical direction from the lower active pattern 112 on the bottom of the first opening 142. In addition, in the selective epitaxial growth process, crystal growth may also be performed in the second direction. Accordingly, each of the epitaxial patterns 150 may have a polygonal shape having a protruding central portion, in a cross-sectional view in the second direction. While an embodiment of FIG. 8 shows certain polygonal shapes of the epitaxial pattern 150, embodiments of the present disclosure are not necessarily limited thereto and the shapes of the epitaxial pattern 150 may vary.

The epitaxial pattern 150 may directly contact both sidewalls of the first to third preliminary nanosheet structures 140a, 140b, and 140c in the first direction, and thus epitaxial pattern 150 may be connected with the first to third preliminary nanosheet structures 140a, 140b, and 140c.

The epitaxial patterns 150 may be referred to as first to third epitaxial patterns 150a, 150b, and 150c depending on positions thereof. The first epitaxial pattern 150a may be disposed between two adjacent first preliminary nanosheet structures 140a (e.g., in the first direction). The second epitaxial pattern 150b may be disposed between the first preliminary nanosheet structure 140a and the third preliminary nanosheet structure 140c that are adjacent to each other (e.g., in the first direction). The third epitaxial pattern 150c may be disposed between the second preliminary nanosheet structures 140b and the third preliminary nanosheet structure 140c that are adjacent to each other (e.g., in the third direction).

As the depth and sidewall profile of the first openings 142 are uniformly formed, the first to third epitaxial patterns 150a, 150b, and 150c in the first openings 142 may have target volumes, respectively (e.g., predetermined desired volumes).

In an embodiment, epitaxial patterns adjacent to both sides of the diffusion break pattern (e.g., the third dummy gate structure) may have different volumes from each other.

In the first multi-bridge channel transistor adjacent to the diffusion break pattern, the first and second epitaxial patterns 150a and 150b may be used as source/drain regions. The first and second epitaxial patterns 150a and 150b may have different volumes from each other. For example, a volume of the second epitaxial pattern 150b may be greater than a volume of the first epitaxial pattern 150a. The source region and drain region of the first multi-bridge channel transistor adjacent to the diffusion break pattern ay have different volumes. Also, the first and second epitaxial patterns 150a and 150b may have different shapes.

In an embodiment, as shown in FIG. 8, one second multi-bridge channel transistor may be formed between adjacent diffusion break patterns (e.g., in the first direction). In this embodiment, the third epitaxial patterns 150c may serve as source/drain regions of the second multi-bridge channel transistor adjacent to the diffusion break pattern. The third epitaxial pattern 150c may have a volume different from volumes of the first and second epitaxial patterns 150a and 150b. The third epitaxial pattern 150c may have a shape different from shapes of the first and second epitaxial patterns 150a and 150b.

The second and third epitaxial patterns 150b and 150c may be formed on both sides of the diffusion break pattern, respectively. The second and third epitaxial patterns 150b and 150c may have different volumes from each other. The second and third epitaxial patterns 150b and 150c may have different shapes from each other.

FIGS. 10, 12, and 14 are cross-sectional views taken along I-I′ portion of FIG. 9. Hereinafter, it may be described with reference to each of cross-sectional views together.

Referring to FIGS. 9 and 10, an insulating interlayer 144 may be formed to cover the first to third epitaxial patterns 150a, 150b, and 150c, the isolation pattern, and the dummy gate structures 130. Thereafter, the insulating interlayer 144 may be planarized until upper surfaces of the dummy gate structures 130 may be exposed.

The first and second dummy gate structures 130a and 130b may be removed to form a first gate trench 146. The first silicon germanium patterns 102a and the first silicon patterns 104a of the first and second preliminary nanosheet structures 140a and 140b may be exposed by the first gate trench 146.

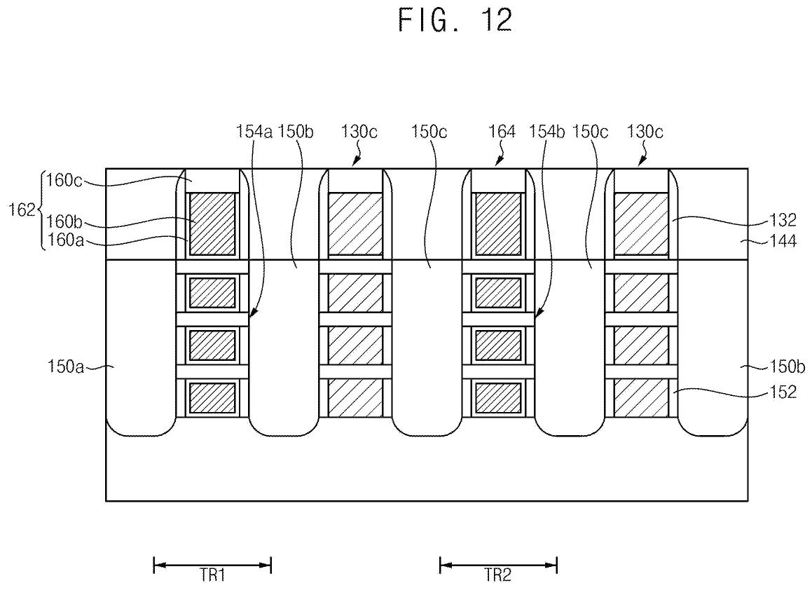

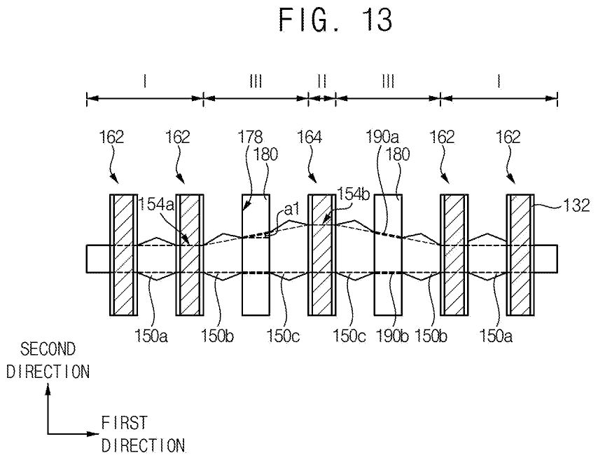

Referring to FIGS. 11 and 12, the first silicon germanium patterns 102a exposed by the first gate trench 146 may be selectively removed to form gaps between the first silicon patterns 104a. The first silicon patterns 104a spaced apart from each other in the vertical direction may serve as each of first and second nano sheet structures 154a and 154b. Each of the nanosheet structures may serve as channel regions of the multi-bridge channel transistor.

The nanosheet structures may include a first nanosheet structure 154a on the first region I and a second nanosheet structure 154b on the second region II. The first nanosheet structure 154a may have the first width in the second direction, and the second nanosheet structure 154b may have the second width in the second direction.

Thereafter, gate structures may be formed to fill the first gate trench 146 and the gaps. A first gate structure 162 may be formed on (e.g., in the vertical direction) the first nanosheet structure 154a, and a second gate structure 164 may be formed on (e.g., in the vertical direction) the second nanosheet structure 154b.

In an embodiment, a thermal oxidation process may be performed on surfaces of the lower active pattern 112 and the first silicon patterns 104a exposed by the first gate trench 146 and the gaps to form an interface layer. A gate insulation layer may be formed on the interface layer. A gate electrode layer may be formed on the gate insulation layer to fill the first gate trench 146 and gaps. In an embodiment, the gate electrode layer may include a metal. Thereafter, in an embodiment the gate electrode layer and the gate insulation layer are planarized until an upper surface of the insulating interlayer 144 may be exposed. Upper portions of the gate electrode layer and the gate insulation layer may be removed, and a capping pattern 160c may be formed on the removed portion. Accordingly, the first and second gate structures 162 and 164 including an interface pattern, a gate insulation pattern 160a, a gate electrode 160b, and a capping pattern 160c may be formed in the first gate trench 146 and the gaps.

By the above process, the first multi-bridge channel transistor TR1 may be formed in the first region I, and the second multi-bridge channel transistor TR2 may be formed in the second region II.

The first multi-bridge channel transistor TR1 adjacent to the diffusion break pattern may include the first gate structure 162, the first epitaxial pattern 150a adjacent to a first side of the first gate structure 162, and the second epitaxial pattern 150b adjacent to a second side of the first gate structure 162. The first and second epitaxial patterns 150a and 150b may serve as a first source region and a first drain region of the first multi-bridge channel transistor TR1, respectively. The first gate structure 162 may extend in the second direction, and may surround the first nanosheet structure 154a.

The second multi-bridge channel transistor TR2 adjacent to the diffusion break pattern may include the second gate structure 164, and third epitaxial patterns 150c adjacent to both sides of the second gate structure 164. The third epitaxial patterns 150c may serve as a second source region and a second drain region of the second multi-bridge channel transistor TR2, respectively. The second gate structure 164 may extend in the second direction, and may surround the second nanosheet structure 154b between the second source region and the second drain region.

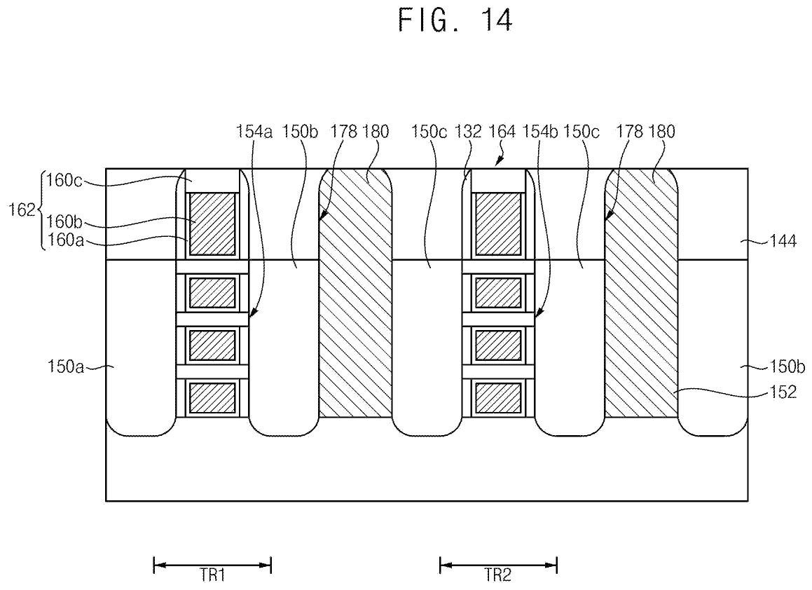

Referring to FIGS. 13 and 14, the third dummy gate structure 130c and the first spacer 132 may be removed. Subsequently, the third preliminary nanosheet structure exposed by removing of the third dummy gate structure 130c and the first spacer 132 may be removed to form a second opening 178.

An insulation material may be filled in the second opening 178 to form a diffusion break pattern 180. Multi-bridge channel transistors adjacent to both sides of the diffusion break pattern 180 may be electrically isolated from each other by the diffusion break pattern 180. In an embodiment, the first and second multi-bridge channel transistors may be electrically isolated from each other by the diffusion break pattern 180.

In the plan view, a first contact point at an end in the second direction between the diffusion break pattern 180 and the second epitaxial pattern 150b and a second contact point at an end in the second direction between the diffusion break pattern 180 and the third epitaxial pattern 150c may be directly connected to form an imaginary first line 190a. In addition, a third contact point of an end in the second direction between the diffusion break pattern 180 and the second epitaxial pattern 150b and a fourth contact point between the diffusion break pattern 180 and the third epitaxial pattern 150c may be directly connected to form an imaginary second line 190b. As shown in FIG. 13, the imaginary second line 190b may be disposed to be opposite the imaginary first line 190a in the second direction.

The imaginary first line 190a may obliquely extend to have an angle al less than about 30 degrees with respect to the first direction. For example, in an embodiment the imaginary first line 190a may obliquely extend to have an angle less than about 15 degrees with respect to the first direction. The imaginary second line 190b may extend in a straight line parallel to the first direction. The imaginary first line 190a may correspond to points along the second side L2 of the mask pattern 106 and the imaginary second line 190b may correspond to points along the first side L1 of the mask pattern 106.

By the above processes, a semiconductor device having the first and second multi-bridge channel transistors adjacent to the diffusion break pattern (e.g., in the first direction) may be manufactured, and defects of the first and second multi-bridge channel transistors adjacent to the diffusion break pattern may be decreased.

The semiconductor device manufactured by the above-described processes may have the following structural characteristics. Since most of features of the semiconductor device may be described above, only main features of the semiconductor device may be described.

The features of the semiconductor device may be described with reference to FIGS. 13 and 14.

Referring to FIGS. 13 and 14 again, a substrate 100 may include a first region I, a second region II and a third region III. The third region III may be the first region disposed between the first and second regions I and II (e.g., in the first direction).

The first region I may be a region where a first gate structure 162 of a first multi-bridge channel transistor TR1 is formed, and the second region II may be a region where a second gate structure 164 of a second multi-bridge channel transistor TR2 is formed. The third region III may be a region where a diffusion break pattern 180 is disposed. The third region III may be positioned between opposite sidewalls of the first and second gate structures 162 and 164 disposed adjacent to each other in the first direction.

A first nanosheet structure 154a may be formed on the first region I of the substrate 100, and a second nanosheet structure 154b may be formed on the second region II of the substrate 100. The first nanosheet structure 154a may have a first width in the second direction, and the second nanosheet structure 154b may have a second width greater than the first width in the second direction.

The first nanosheet structure 154a and the second nanosheet structure 154b may be spaced apart from each other in the first direction. First sidewalk of the first and second nanosheet structures 154a and 154b positioned in the second direction may be aligned with each other in the first direction and may be arranged along a straight line extending in the first direction. Second sidewalls of the first and second nanosheet structures 154a and 154b in the second direction may not be aligned with each other in the first direction and may not extend along a straight line extending in the first direction. In the plan view, first sides (e.g., lower sides in the second direction) of the first and second nanosheet structures 154a and 154b may be aligned in the first direction, and may be arranged in a straight line extending in the first direction. The second sides (e.g., upper sides in the second direction) facing the first sides of the first and second nanosheet structures 154a and 154b may not be aligned along a straight line extending in the first direction.

The first gate structure 162 may be formed on the first nanosheet structure 154a, and the second gate structure 164 may be formed on the second nanosheet structure 154b. First spacers 132 may be formed on sidewalls of the first gate structure 162 and sidewalls of the second gate structure 164.

A first epitaxial pattern 150a may be formed between the first nanosheet structures 154a (e.g., in the first direction). A second epitaxial pattern 150b may be formed between the first nanosheet structure 154a and the diffusion break pattern 180 (e.g., in the first direction). A third epitaxial pattern 150c may be formed between the second nanosheet structure 154b and the diffusion break pattern 180 (e.g., in the first direction).

As such, the first and second nanosheet structures 154a and 154b and the first to third epitaxial patterns 150a, 150b and 150c may be connected in the first direction to form active structures. The active structures may be separated from each other (e.g., electrically isolated therefrom) at a portion where the diffusion break pattern 180 is formed.

The first multi-bridge channel transistor TR1 adjacent to the diffusion break pattern 180 may include the first gate structure 162 on the first nanosheet structure 154a and the first and second epitaxial patterns 150a and 150b. The first and second epitaxial patterns 150a, and 150b may have different volumes from each other. For example, the volume of the second epitaxial pattern 150b may be greater than the volume of the first epitaxial pattern 150a. A source region and a drain region of the first multi-bridge channel transistor adjacent to the diffusion break pattern may have different volumes from each other. Also, the first and second epitaxial patterns 150a and 150b may have different shapes from each other.

A second multi-bridge channel transistor adjacent to the diffusion break pattern may include the second gate structure 164 on the second nanosheet structure 154b and the third epitaxial patterns 150c. The third epitaxial patterns 150c may have a volume different from the volumes of the first and second epitaxial patterns 150a and 150b. The third epitaxial pattern may have a shape different from the shapes of the first and second epitaxial patterns.

Epitaxial patterns formed on both sides of the diffusion break pattern 180 may have different volumes from each other. The second and third epitaxial patterns 150b and 150c may be formed on both sides of the diffusion break pattern 180, respectively. The second and third epitaxial patterns 150b and 150c may have different volumes from each other. The second and third epitaxial patterns 150b and 150c may have different shapes from each other.

In the plan view, a first contact point at an end in the second direction where the diffusion break pattern 180 and the second epitaxial pattern 150b and a second contact point at an end in the second direction between the diffusion break pattern 180 and the third epitaxial pattern 150c may be directly connected to form an imaginary first line 190a. In addition, a third contact point of an end in the second direction between the diffusion break pattern 180 and the second epitaxial pattern 150b and a fourth contact point between the diffusion break pattern 180 and the third epitaxial pattern 150c may be directly connected to form an imaginary second line 190b. The imaginary second line 190b may be disposed to be opposite to the imaginary first line 190a in the second direction.

The imaginary first line 190a may obliquely extend to have an angle less than about 30 degrees with respect to the first direction. For example, in an embodiment the imaginary first line 190a may obliquely extend to have an angle less than about 15 degrees with respect to the first direction. The imaginary second line 190b may extend in a straight line parallel to the first direction.

In the process of manufacturing the semiconductor device, a first fin structure may be formed on the first to third regions I, II, and III. The first fin structure formed on the third region III may have one first side extending in the first direction and having a straight line shape, and the other side extending in oblique direction and having an angle less than about 30 degrees with respect to the first direction. Therefore, in the semiconductor device, the imaginary first line 190a may obliquely extend to have the angle less than about 30 degrees with respect to the first direction.

Therefore, the imaginary lines directly connecting the contact point of the end in the second direction between the diffusion break pattern 180 and the second epitaxial pattern 150b and the contact point of the end in the second direction between the diffusion break pattern 180 and the third epitaxial pattern 150c may obliquely extend to have the angle less than about 30 degrees with respect to the first direction.

A semiconductor device according to various embodiments in which the imaginary lines directly connecting the contact point of the end in the second direction between the diffusion break pattern and the second epitaxial pattern and the contact point of the end in the second direction between the diffusion break pattern and the third epitaxial pattern may extend to have the angle less than about 30 degrees with respect to the first direction may be provided.

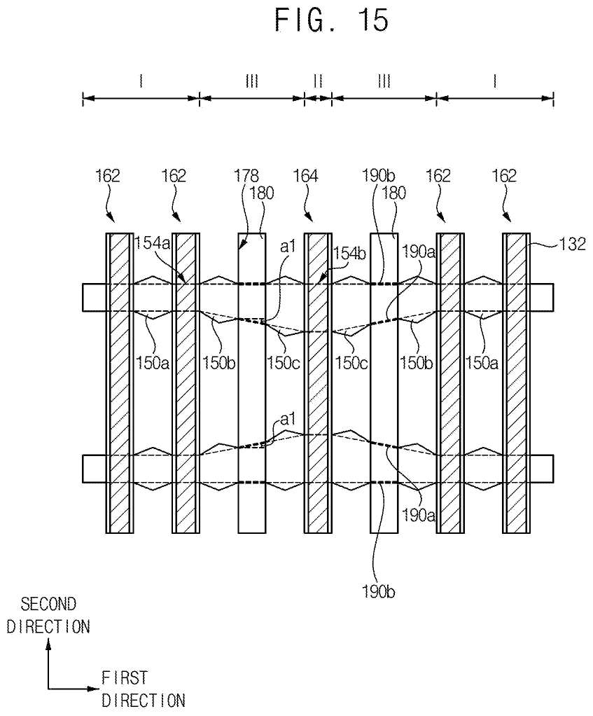

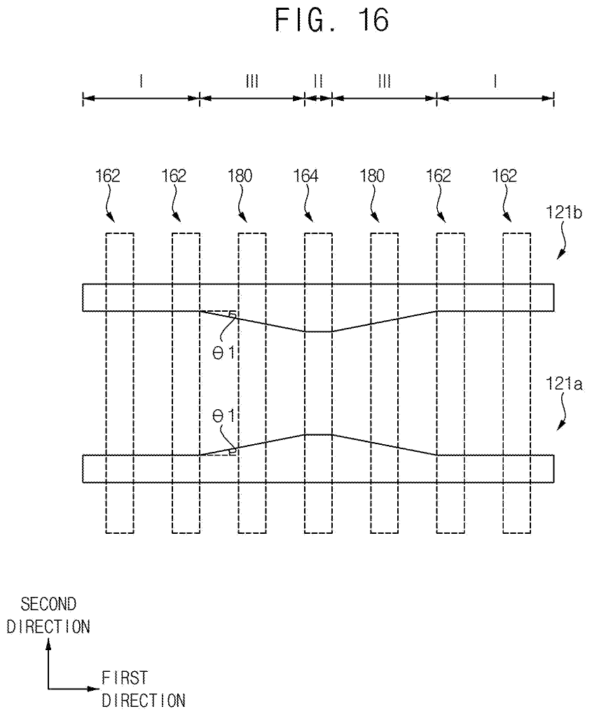

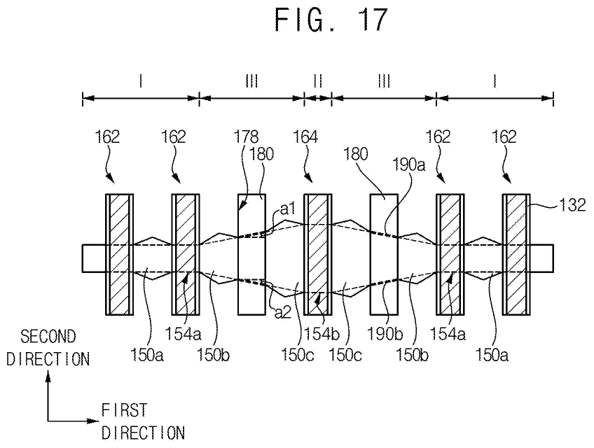

FIG. 15 is a plan view of a semiconductor device according to an embodiment of the present disclosure. FIG. 16 is a plan view of a first fin structure formed in a manufacturing process of a semiconductor device according to an embodiment of the present disclosure.

Referring to FIGS. 15 and 16, the semiconductor device may have a first active structure including the first and second nanosheet structures 154a and 154b and the first to third epitaxial patterns 150a, 150b and 150c connected in the first direction. The first active structure may be substantially the same as the active structure described with reference to FIGS. 13 and 14.

In an embodiment, a second active structure may be disposed to be opposite to the first active structure in the second direction. The first and second active structures may be spaced apart from each other in the second direction, and the first and second active structures may be adjacent to each other in the second direction. The first and second active structures may be symmetric to each other with respect to the first direction.

The first and second active structures may be substantially the same as each other and may be symmetrical to each other. The second active structure may include the first and second nanosheet structures 154a and 154b and the first to third epitaxial patterns 150a, 150b, and 150c connected in the first direction.

Each of the first and second active structures may be separated at a portion where the diffusion break pattern 180 is formed. The diffusion break pattern 180 may extend in the second direction.

A first gate structure 162 extending in the second direction may be formed on the first nanosheet structures 154a included in the first and second active structures. One first gate structure 162 may extend to cover the first nanosheet structures 154a of the first and second active structures that are disposed to be parallel to each other.

A second gate structure 164 extending in the second direction may be formed on the second nanosheet structures 154b included in the first and second active structures. One second gate structure 164 may extend to cover the second nanosheet structures 154b of the first and second active structures that are disposed to be parallel to each other.

In the plan view, in each of the first and second active structures, a first contact point at an end in the second direction between the diffusion break pattern 180 and the second epitaxial pattern 150b and a second contact point at an end in the second direction between the diffusion break pattern 180 and the third epitaxial pattern 150c may be directly connected to form an imaginary first line 190a. In addition, a third contact point of an end in the second direction between the diffusion break pattern 180 and the second epitaxial pattern 150b and a fourth contact point between the diffusion break pattern 180 and the third epitaxial pattern 150c may be directly connected to form an imaginary second line 190b facing the imaginary first line 190a in the second direction. The imaginary first line 190a in the second active structure may be on a lower side (e.g., in the second direction) and the imaginary second line 190b of the second active structure may be on an upper side (e.g., in the second direction).

The imaginary first line 190a may obliquely extend to have an angle al less than about 30 degrees with respect to the first direction. For example, the imaginary first line 190a may obliquely extend to have an angle al less than about 15 degrees with respect to the first direction. The imaginary second line 190b may extend in a straight line parallel to the first direction.

In manufacturing of the semiconductor device, as shown in FIG. 16, the first fin structure 121a and the second fin structure 121b may be formed on the first to third regions I, II, and III. The first and second fin structures 121a and 121b may be arranged in parallel to each other and may be spaced apart from each other in the second direction.

The first fin structure 121a on the third region III may have one side (e.g., a lower side) extending in the first direction and having a straight line shape, and the other side (e.g., an upper side) obliquely extending to have an angle θ1 less than about 30 degrees with respect to the first direction. In addition, the second fin structure 121b on the third region III and the first fin structure 121a may be symmetrical to each other with respect to the first direction. One side (e.g., an upper side in the second direction) of the second fin structure 121b on the third region III may extend to have a straight line shape parallel to the first direction, and the other side (e.g., a lower side in the second direction) of the second fin structure 121b on the third region III may obliquely extend to have the angle θ1 less than about 30 degrees. Therefore, in the semiconductor device, the imaginary first lines 190a may obliquely extend to have the angle less than about 30 degrees with respect to the first direction.

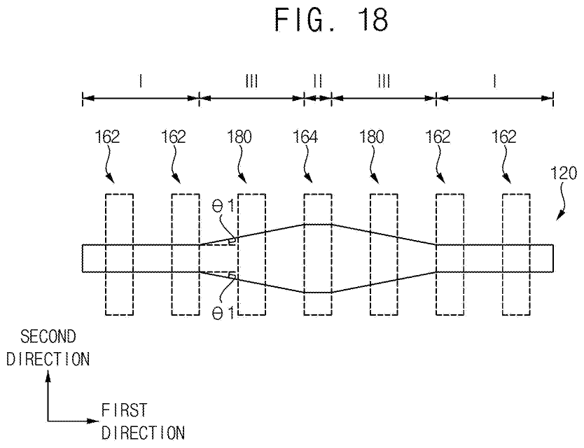

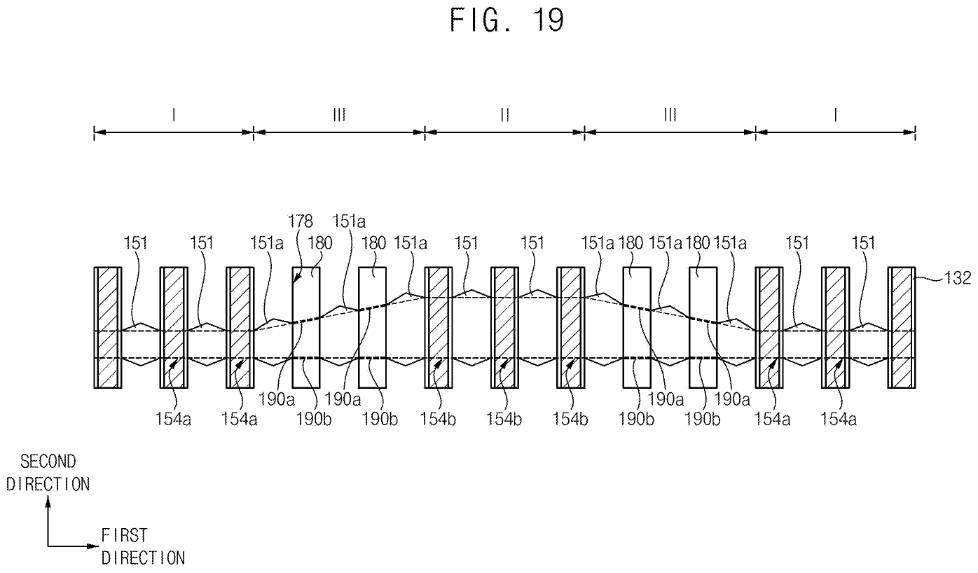

FIG. 17 is a plan view of a semiconductor device according to an embodiment of the present disclosure. FIG. 18 is a plan view of a first fin structure formed in a manufacturing process of a semiconductor device according to an embodiment of the present disclosure.

Referring to FIG. 17, the semiconductor device may have an active structure including first and second nanosheet structures 154a and 154b and first to third epitaxial patterns 150a, 150b and 150c connected in the first direction. The active structures may be separated from each other (e.g., electrically isolated from each other) at a portion where the diffusion break pattern 180 is formed.

The first nanosheet structure 154a may be formed on the first region I of the substrate 100, and the second nanosheet structure 154b may be formed on the second region II of the substrate 100.

The first gate structure 162 may be formed on the first nanosheet structure 154a, and the second gate structure 164 may be formed on the second nanosheet structure 154b. The first spacers 132 may be formed on the sidewalls of the first gate structure 162 and the sidewalls of the second gate structure 164.

The first nanosheet structure 154a and the second nanosheet structure 154b may be spaced apart from each other in the first direction. The first sidewalls of the first and second nanosheet structures 154a and 154b positioned in the second direction may not be aligned on a straight line extending in the first direction. The second sidewalls of the first and second nanosheet structures 154a and 154b in the second direction may not be aligned on a straight line extending in the first direction. In a plan view, in the first and second nanosheet structures, first sides (e.g., lower sides in the second direction) may not be aligned on a straight line extending in the first direction, and second sides (e.g., upper sides in the second direction) facing the first sides may not be aligned on a straight line extending in the first direction.

In the plan view, in each of the active structures, a first contact point at an end in the second direction between the diffusion break pattern 180 and the second epitaxial pattern 150b and a second contact point at an end in the second direction between the diffusion break pattern 180 and the third epitaxial pattern 150c may be directly connected to form an imaginary first line 190a. In addition, a third contact point of an end in the second direction between the diffusion break pattern 180 and the second epitaxial pattern 150b and a fourth contact point between the diffusion break pattern 180 and the third epitaxial pattern 150c may be directly connected to form an imaginary second line 190b facing the imaginary first line 190a in the second direction.

The imaginary first line 190a may obliquely extend to have an angle a1 less than about 30 degrees with respect to the first direction. For example, in an embodiment the imaginary first line 190a may obliquely extend to have an angle al less than about 15 degrees with respect to the first direction. The imaginary second line 190b may Obliquely extend to have an angle a2 less than about 30 degrees with respect to the first direction. For example, the imaginary second line 190b may obliquely extend to have an angle a2 less than about 15 degrees with respect to the first direction.

In manufacturing of the semiconductor device, as shown in FIG. 18, a first fin structure 120 may be formed on the first to third regions I, II, and III. In the first fin structure 120 on the third region each of a first side (e.g., an upper side in the second direction) and a second side (e.g., a lower side in the second direction) may obliquely extend to have an angle θ1 less than about 30 degrees with respect to the first direction. Therefore, in the semiconductor device, each of the imaginary first line 190a and the imaginary second line 190b may obliquely extend to have an angle less than about 30 degrees with respect to the first direction.

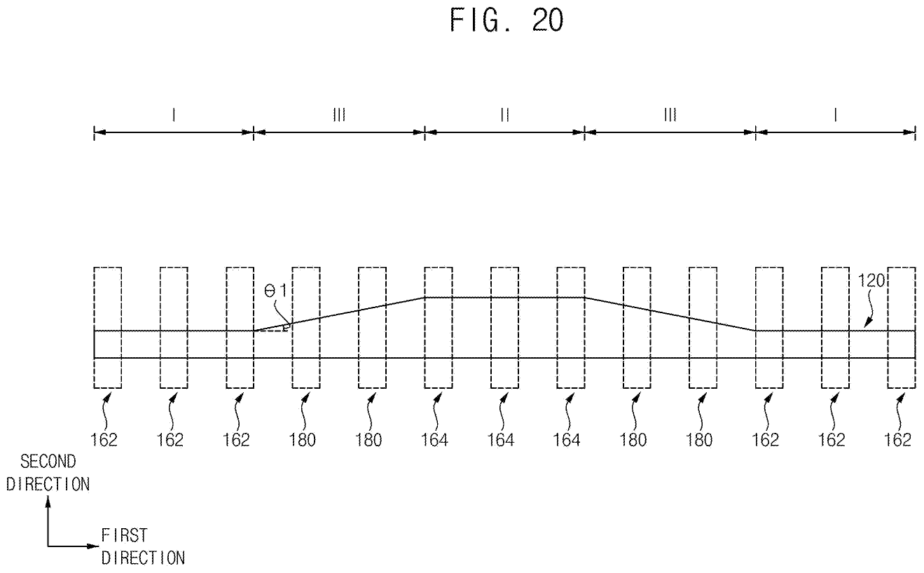

FIG. 19 is a plan view of a semiconductor device according to an embodiment of the present disclosure. FIG. 20 is a plan view of a first fin structure formed in a manufacturing process of a semiconductor device according to an embodiment of the present disclosure.

Referring to FIG. 19, the semiconductor device may have an active structure including first and second nanosheet structures 154a and 154b and epitaxial patterns 151 and 151a connected in the first direction. The active structures may be separated from each other (e.g., electrically isolated therefrom) at a portion where the diffusion break pattern 180 is formed.

A plurality of first nanosheet structures 154a spaced apart from each other may be formed on the first region I of the substrate, and a plurality of second nanosheet structures 154b spaced apart, from each other may be formed on the second region II of the substrate.

The first gate structure 162 may be formed on each of the first nanosheet structures 154a, and the second gate structure 164 may be formed on each of the second nanosheet structures 154b. The first spacers 132 may be formed on the sidewalls of the first gate structure 162 and the sidewalls of the second gate structure 164.

In the plan view, first sides (e.g., lower sides in the second direction) of the first and second nanosheet structures 154a and 154b may be arranged on a straight line extending in the first direction. Second sides (e.g., an upper side in the second direction) facing the first sides in the second direction of the first and second nanosheet structures 154a and 154b may not be aligned on a straight line extending in the first direction.

In the plan view, a plurality of diffusion break patterns 180 spaced apart from each other may be formed between the active structures (e.g., in the first direction).

The epitaxial patterns 151a formed on both sides of the diffusion break pattern 180 may have different volumes from each other.

in the plan view contact points at ends in the second direction between the diffusion break pattern 180 and the epitaxial pattern 151a adjacent to both sides the diffusion break pattern 180 may be directly connected to form an imaginary first line 190a. In addition, contact points of ends in the second direction between the diffusion break pattern 180 and the epitaxial pattern 150b adjacent to both sides the diffusion break pattern 180 may be directly connected to form an imaginary second line 190b facing the imaginary first line in the second direction.

The imaginary first line 190a may obliquely extend to have an angle less than about 30 degrees with respect to the first direction. For example, in an embodiment the imaginary first line 190a may obliquely extend to have an angle less than about 15 degrees with respect to the first direction. The imaginary second line 190b may extend in a straight line parallel to the first direction.

In the manufacturing of the semiconductor device, as shown in FIG. 20, a first fin structure 120 may be formed on the first to third regions I, II, and III. The first fin structure 120 on the third region III may have one first side (e.g., a lower side in the second direction) extending in the first direction and having a straight line shape, and the other side (e.g., an upper side in the second direction) obliquely extending and having an angle θ1 less than about 30 degrees with respect to the first direction. Therefore, in the semiconductor device, each of the imaginary first lines 190a may obliquely extend to have an angle less than about 30 degrees with respect to the first direction.

The foregoing is illustrative of example embodiments of the present disclosure and is not to be construed as limiting thereof. Although a few embodiments have been described, those skilled in the art will readily appreciate that many modifications are possible without materially departing from the novel teachings and advantages of the present disclosure. Accordingly, all such modifications are intended to be included within the scope of the present disclosure. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the present disclosure.

What is claimed is:

1. A semiconductor device, comprising:
a first nanosheet structure on a substrate, the first nanosheet structure having a first width in a second direction parallel to an upper surface of the substrate, the first nanosheet structure including silicon patterns that are spaced apart from each other in a vertical direction perpendicular to the upper surface of the substrate;
a second nanosheet structure spaced apart from the first nanosheet structure in a first direction perpendicular to the second direction on the substrate and parallel to the upper surface of the substrate, the second nanosheet structure having a second width in the second direction greater than the first width, and the second nanosheet structure including silicon patterns that are spaced apart from each other in the vertical direction;
a diffusion break pattern disposed between the first and second nanosheet structures in the first direction;
a first epitaxial pattern disposed between the first nanosheet structure and the diffusion break pattern in the first direction, the first epitaxial pattern directly contacting the first nanosheet structure and the diffusion break pattern, respectively; and
a second epitaxial pattern disposed between the second nanosheet structure and the diffusion break pattern in the first direction, the second epitaxial pattern directly contacting the second nanosheet structure and the diffusion break pattern, respectively,
wherein at least one of imaginary first lines connecting a first contact point of an end portion positioned in the second direction between the diffusion break pattern and the first epitaxial pattern and a second contact point at an end portion in the second direction between the diffusion break pattern and the second epitaxial pattern extends to have an angle less than about 30 degrees with respect to the first direction.

3. The semiconductor device of claim 1, wherein a volume of the first epitaxial pattern and a volume of the second epitaxial pattern are different from each other.

3. The semiconductor device of claim 1, wherein at least one of imaginary second lines connecting a third contact point of an end portion positioned in the second direction between the diffusion break pattern and the first epitaxial pattern and a fourth contact point at an end portion positioned in the second direction between the diffusion break pat ern and the second epitaxial pattern extends parallel to the first direction.

4. The semiconductor device of claim 1, further comprising gate structures covering each of the first and second nanosheet structures and extending in the second direction.

5. The semiconductor device of claim 1, wherein at least one of the imaginary first lines extends to have an angle less than about 15 degrees with respect to the first direction.

6. A semiconductor device, comprising:
a plurality of first nanosheet structures on a substrate, the plurality of first nanosheet structures are spaced apart from each other in a first direction parallel to an upper surface of the substrate, each of the plurality of first nanosheet structures having a first width in a second direction perpendicular to the first direction and parallel to the upper surface of the substrate, wherein each of the plurality of first nanosheet structures includes silicon patterns that are spaced apart from each other in a vertical direction perpendicular to the upper surface of the substrate;
a second nanosheet structure spaced apart from the plurality of first nanosheet structures in the first direction on the substrate, the second nanosheet structure having a second width in the second direction greater than the first width, wherein the second nanosheet structure includes silicon patterns that are spaced apart from each other in the vertical direction;
a diffusion break pattern disposed between a first nanosheet structure of the plurality of first nanosheet structures and the second nanosheet structure that are adjacent to each other in the first direction;
a first epitaxial pattern between adjacent first nanosheet structures of the plurality of first nanosheet structures;
a second epitaxial pattern disposed between the first nanosheet structure and the diffusion break pattern, the second epitaxial pattern directly contacting the first nanosheet structure and the diffusion break pattern, respectively;
a third epitaxial pattern disposed between the second nanosheet structure and the diffusion break pattern, the third epitaxial pattern directly contacting; the second nanosheet structure and the diffusion break pattern, respectively;
first gate structures covering the plurality of first nanosheet structures, the first gate structures extending in the second direction; and
a second gate structure covering the second nanosheet structure, the second gate structure extending in the second direction,
wherein a volume of the first epitaxial pattern and a volume of the second epitaxial pattern are different from each other.

7. The semiconductor device of claim 6, wherein the first epitaxial pattern and the second epitaxial pattern have different shapes from each other, in a plan view.

8. The semiconductor device of claim 6, at least one of imaginary first lines connecting a first contact point of an end portion positioned in the second direction between the diffusion break pattern and the second epitaxial pattern and a second contact point at an end portion positioned in the second direction between the diffusion break pattern and the third epitaxial pattern extends to have an angle less than about 30 degrees with respect to the first direction.

9. The semiconductor device of claim 6, wherein at least one of imaginary second lines connecting a third contact point of an end portion positioned in the second direction between the diffusion break pattern and the second epitaxial pattern and a fourth contact point at an end portion positioned in the second direction between the diffusion break pattern and the third epitaxial pattern extends parallel to the first direction.

10. The semiconductor device of claim 6, wherein a volume of the second epitaxial pattern and a volume of the third epitaxial pattern are different from each other.

11. The semiconductor device of claim 6, further comprising a first transistor comprised of the first nanosheet structure, a first gate structure of the first gate structures, and epitaxial patterns on both sides of the first nanosheet structure, wherein a plurality of first transistors are connected to each other in the first direction.

12. The semiconductor device of claim 11, wherein, in the first transistor, an epitaxial pattern that directly contacts the diffusion break pattern has a volume different from a volume of an epitaxial pattern that directly contacts the first nanosheet structure and does not directly contact the diffusion break pattern.

13. The semiconductor device of claim 6, further comprising a second transistor comprised of the second nanosheet structure, the second gate structure, and epitaxial patterns on both sides of the second nanosheet structure, wherein a plurality of second transistors are connected to each other in the first direction.

14. The semiconductor device of claim 13, wherein, in the second transistor, an epitaxial pattern directly contacting the diffusion break pattern has a volume different from a volume of an epitaxial pattern that directly contacts the second nanosheet structure and does not directly contact the diffusion break pattern.

15. A semiconductor device, comprising:
a first transistor on a substrate, the first transistor including a first nanosheet structure having a first width in a second direction parallel to an upper surface of the substrate, a first gate structure covering the first nanosheet structure and extending in the second direction, and first epitaxial patterns on both sides of the first gate structure, the first epitaxial patterns are directly connected to the first nanosheet structure;
a second transistor on the substrate, the second transistor including a second nanosheet structure having a second width in the second direction greater than the first width, a second gate structure covering the second nanosheet structure and extending in the second direction, and second epitaxial patterns on both sides of the second gate structure, the second epitaxial patterns are directly connected to the second nanosheet structure; and
a diffusion break pattern disposed between the first transistor and the second transistor,
wherein the first and second transistors are electrically isolated from each other by the diffusion break pattern,
wherein a first side of the diffusion break pattern directly contacts one of the first epitaxial patterns, and a second side of the diffusion break pattern directly contacts one of the second epitaxial patterns, and
wherein at least one of imaginary lines connecting a first contact point of an end portion positioned in the second direction between the diffusion break pattern and a first epitaxial pattern of the first epitaxial patterns and a second contact point at an end portion positioned ire the second direction between the diffusion break pattern and a second epitaxial pattern of the second epitaxial patterns extends to have an angle less than about 30 degrees with respect to a first direction perpendicular to the second direction and parallel to the upper surface of the substrate.

16. The semiconductor device of claim 15, wherein a first epitaxial pattern of the first epitaxial patterns that directly contacts the diffusion break pattern has a volume different from a volume of a first epitaxial pattern of the first epitaxial patterns that does not directly contact the diffusion break pattern.

17. The semiconductor device of claim 15, wherein a second epitaxial pattern of the second epitaxial patterns that directly contacts the diffusion break pattern has a volume different from a volume of a second epitaxial pattern of the second epitaxial patterns that does not directly contact the diffusion break pattern.

18. The semiconductor device of claim 15, wherein a first epitaxial pattern of the first epitaxial patterns that directly contacts the diffusion break pattern and a second epitaxial pattern of the second epitaxial patterns that directly contacts the diffusion break pattern have different volumes from each other.

19. The semiconductor device of claim 15, wherein the first transistor includes a plurality of first transistors, and the plurality of first transistors are connected in the first direction.

20. The semiconductor device of claim 15, wherein the second transistor includes a plurality of second transistors, and the plurality of second transistors are connected in the first direction.
